(19) United States
(12) Patent Application Publication
(10) Pub. No.: US 2025/0287827 A1
(43) Pub. Date: Sep. 11, 2025

(54) DISPLAY APPARATUS

(71) Applicant: Samsung Display Co., LTD., Yongin-si (KR)

(72) Inventors: Mankyu Jo, Yongin-si (KR); Seungjun Lee, Yongin-si (KR)

(21) Appl. No.: 18/939,406

(22) Filed: Nov. 6, 2024

(30) Foreign Application Priority Data
Mar. 8, 2024 (KR) 10-2024-0033321

(51) Int. Cl. H10K 77/10; G09G 3/3233; H10K 102/00; H10N 30/20; H10N 30/857

(52) U.S. Cl. CPC H10K 77/111; H10N 30/206; H10N 30/857; G09G 3/3233; G09G 2300/0426; G09G 2300/0819; G09G 2300/0842; H10K 2102/311

(57) ABSTRACT

A display apparatus including: a substrate comprising a plurality of emission areas and a non-emission area between the plurality of emission areas; at least one light-emitting diode in each of the plurality of emission areas; a sensing line crossing the non-emission area; one or more actuators in the non-emission area; a sensing portion configured to sense a deformation rate of the substrate from the sensing line; and a correction control portion configured to drive the one or more actuators.

### CROSS-REFERENCE TO RELATED APPLICATION

The present application claims priority to and the benefit of Korean Patent Application No. 10-2024-0033321, filed on Mar. 8, 2024, in the Korean Intellectual Property Office, the entire disclosure of which is incorporated herein by reference.

### BACKGROUND

### 1. Field

Aspects of one or more embodiments relate to a display apparatus.

### 2. Description of the Related Art

With the development of display apparatuses for visually displaying electrical signals, various display apparatuses with excellent characteristics, such as relatively small thickness, relatively small weight, relatively reduced power consumption, etc., have been introduced. For example, flexible display apparatuses which may be folded or rolled have been introduced. Recently, display apparatuses of various structures, such as stretchable display apparatuses, which may be changed to have various shapes, have been actively researched and developed.

The above information disclosed in this Background section is only for enhancement of understanding of the background and therefore the information discussed in this Background section does not necessarily constitute prior art.

### SUMMARY

Aspects of one or more embodiments relate to a display apparatus, and for example, to a flexible display apparatus.

Additional aspects will be set forth in part in the description which follows and, in part, will be apparent from the description, or may be learned by practice of the presented embodiments of the disclosure.

According to one or more embodiments, a display apparatus includes a substrate including a plurality of emission areas and a non-emission area arranged between the plurality of emission areas, at least one light-emitting diode arranged in each of the plurality of emission areas, a sensing line crossing the non-emission area, one or more actuators arranged in the non-emission area, a sensing portion configured to sense a deformation rate of the substrate from the sensing line, and a correction control portion configured to drive the one or more actuators.

According to some embodiments, the deformation rate of the substrate may be measured from at least one value from among a resistance change, a capacitance change, and a waveform change according to an electrical signal of the sensing line.

According to some embodiments, the sensing portion may include a memory portion configured to store a reference value of a characteristic of the sensing line and a sensing circuit configured to calculate the deformation rate of the substrate by comparing the reference value stored in the memory portion with the characteristic of the sensing line.

According to some embodiments, the correction control portion may include a correction circuit configured to generate a correction value by comparing an average deformation rate of the plurality of emission areas with a deformation rate of each of the plurality of emission areas and an actuator circuit configured to generate, based on the correction value, a driving signal for driving the one or more actuators.

According to some embodiments, a modulus of the non-emission area may be less than a modulus of the emission area.

According to some embodiments, the one or more actuators may include a first actuator and a second actuator, wherein the first actuator is a stretching actuator and the second actuator is a shrinkage actuator.

According to some embodiments, the one or more actuators may include soft actuators.

According to some embodiments, the one or more actuators may include dielectric elastomer actuators each including a first electrode layer, an elastomer layer, and a second electrode layer.

According to some embodiments, the display apparatus may further include a scan line crossing the plurality of emission areas and extending in a first direction, wherein the sensing line extends in a second direction crossing the first direction.

According to some embodiments, the at least one light-emitting diode may include an organic light-emitting diode or an inorganic light-emitting diode.

According to one or more embodiments, a display apparatus includes a substrate including a plurality of emission areas and a non-emission area arranged between the plurality of emission areas, at least one light-emitting diode arranged in each of the plurality of emission areas, a scan line crossing the plurality of emission areas and extending in a first direction, a sensing line crossing the non-emission area and extending in a second direction crossing the first direction, and a first actuator and a second actuator arranged in the non-emission area, wherein the first actuator includes a stretching actuator and the second actuator includes a shrinkage actuator.

According to some embodiments, a modulus of the non-emission area may be less than a modulus of the emission area.

The display apparatus may further include an inorganic insulating layer between the substrate and the at least one light-emitting diode, wherein the inorganic insulating layer has an opening corresponding to the non-emission area.

According to some embodiments, an organic material layer may be in the opening of the inorganic insulating layer.

According to some embodiments, the first actuator and the second actuator may be arranged between adjacent emission areas in the first direction.

According to some embodiments, each of the first actuator and the second actuator may include a dielectric elastomer actuator including a first electrode layer, an elastomer layer, and a second electrode layer.

According to some embodiments, the display apparatus may further include a sensing portion configured to sense a deformation rate of the substrate from the sensing line and a correction control potion configured to drive the first actuator and the second actuator.

According to some embodiments, the deformation rate of the substrate may be measured from at least one value from among a resistance change, a capacitance change, and a waveform change according to an electrical signal of the sensing line.

According to some embodiments, the sensing portion may include a memory portion configured to store a reference value of a characteristic of the sensing line and a sensing circuit configured to calculate the deformation rate by comparing the reference value stored in the memory portion with the characteristic of the sensing line.

According to some embodiments, the correction control portion may include a correction circuit configured to generate a correction value by comparing an average deformation rate of the plurality of emission areas with a deformation rate of each of the plurality of emission areas and an actuator circuit configured to generate, based on the correction value, a driving signal for driving the first and second actuators.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a schematic perspective view of a display apparatus according to some embodiments;

FIGS. 2A and 2B are perspective views showing the display apparatus of FIG. 1 stretched in a first direction;

FIG. 2C is a perspective view showing the display apparatus of FIG. 1 stretched in a second direction;

FIG. 2D is a perspective view showing the display apparatus of FIG. 1 stretched in a first direction and a second direction;

FIG. 2E is a perspective view showing the display apparatus of FIG. 1 stretched in a third direction;

FIG. 3 is a schematic plan view of a display apparatus according to some embodiments;

FIGS. 4A to 4C are each an equivalent circuit diagram of a sub-pixel of a display apparatus according to some embodiments;

FIGS. 5A to 5C are schematic cross-sectional views of a portion of a display area applicable to a display apparatus according to some embodiments;

FIG. 6A is a schematic enlarged plan view of a portion of a display apparatus, the portion corresponding to region I of FIG. 3, according to some embodiments;

FIGS. 6B and 6C are schematic plan views to describe an operation when deformation occurs in a display apparatus according to some embodiments;

FIG. 7 is an example of a flowchart of a driving operation of a display apparatus according to some embodiments;

FIG. 8 is a schematic view of elements of a sensing portion and a correction control portion according to some embodiments;

FIG. 9 is a schematic enlarged plan view of a portion of a display apparatus according to some embodiments;

FIG. 10 is a view of an example of an applicable actuator, according to some embodiments;

FIGS. 11A to 11C are schematic cross-sectional views of a portion of a display apparatus according to some embodiments; and

FIGS. 12A to 12G are schematic perspective views of electronic devices including a display apparatus according to some embodiments.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of various modifications and alternative forms, embodiments thereof are shown by way of example in the drawings and will herein be described in detail. Effects and characteristics of the disclosure and methods of achieving the same will become apparent by referring to the embodiments described in detail below along with the drawings. However, the disclosure is not limited to the embodiments disclosed hereinafter and may be realized in various forms.

Hereinafter, embodiments will be described in detail by referring to the accompanying drawings, wherein, when describing the accompanying drawings, elements that are the same as or corresponding to each other will be assigned the same reference numerals, repeated descriptions thereof will not be given.

In the embodiments described hereinafter, the terms “first,” “second,” etc. are used to distinguish an element from another and are not used as a restrictive sense.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or elements, but do not preclude the presence or addition of one or more other features or elements.

It will be understood that when a layer, region, or element is referred to as being formed “on” another layer, area, or element, it can be directly or indirectly formed on the other layer, region, or element. That is, for example, intervening layers, regions, or elements may be present.

Sizes of elements in the drawings may be exaggerated for convenience of explanation. For example, sizes and thicknesses of the elements in the drawings are randomly indicated for convenience of explanation, and thus, the disclosure is not necessarily limited to the illustrations of the drawings.

When a certain embodiment may be implemented differently, a specific process order may be performed differently from the described order. For example, two consecutively described processes may be performed substantially at the same time or performed in an order opposite to the described order.

In this specification, the expression “A and/or B” may indicate A, B, or A and B. Also, the expression “at least one of A or B” may indicate A, B, or A and B.

In the embodiments hereinafter, it will be understood that when an element, an area, or a layer is referred to as being connected to another element, area, or layer, it can be directly and/or indirectly connected to the other element, area, or layer. For example, it will be understood in this specification that when an element, an area, or a layer is referred to as being in contact with or being electrically connected to another element, area, or layer, it can be directly and/or indirectly in contact with or electrically connected to the other element, area, or layer.

An x-axis, a y-axis and a z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

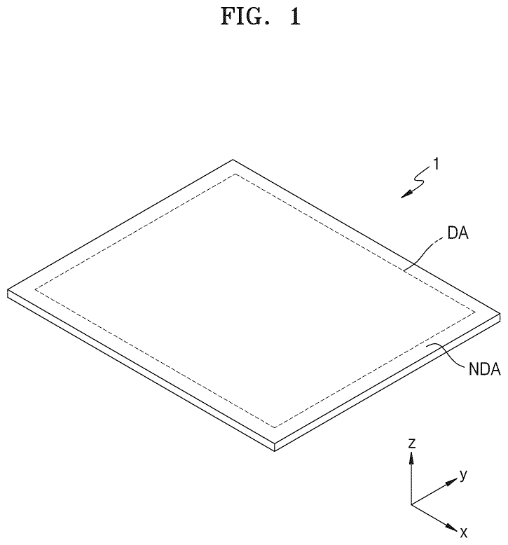

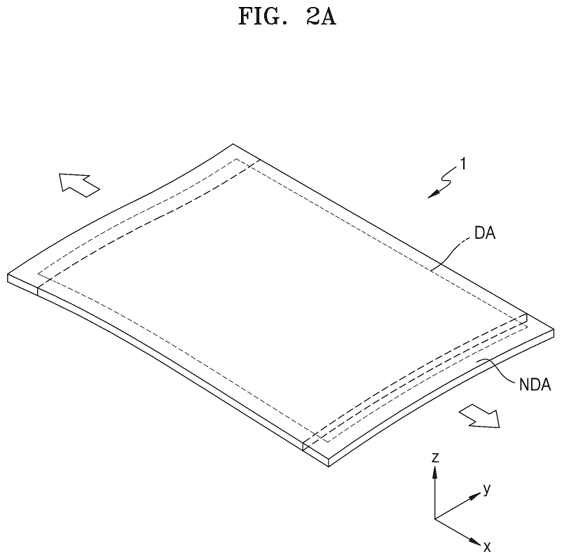

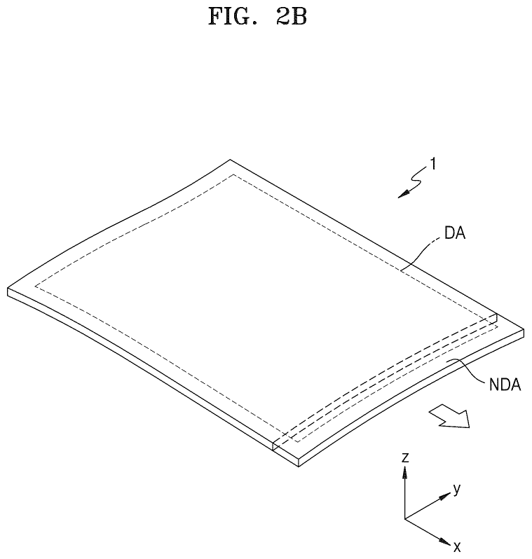

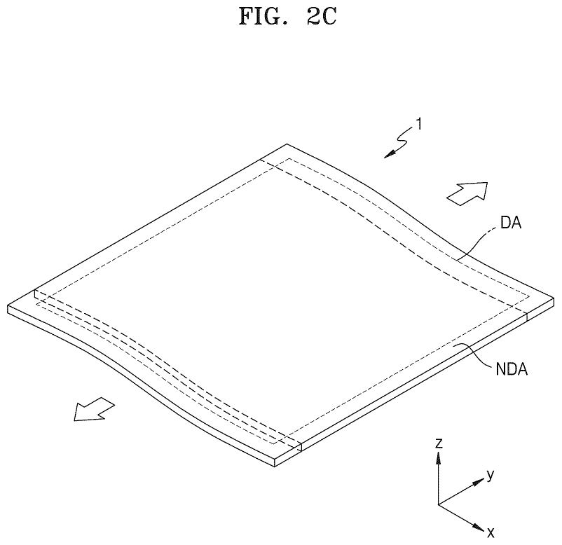

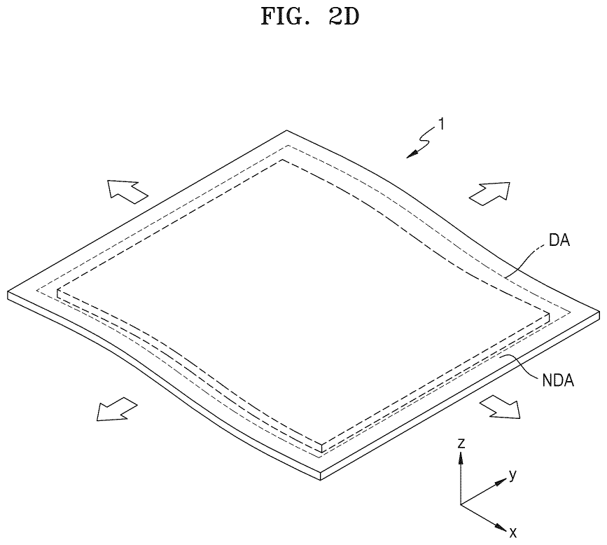

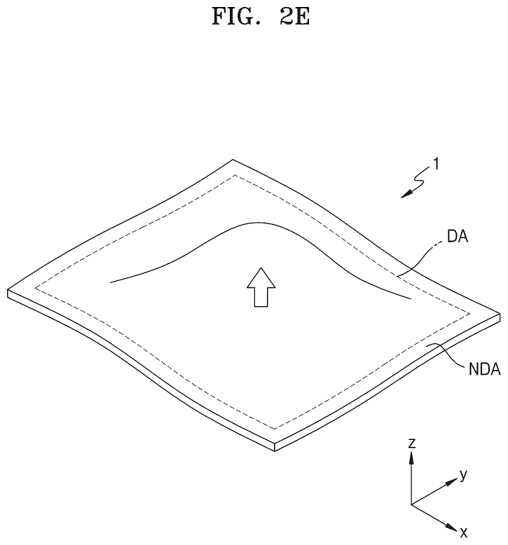

FIG. 1 is a schematic perspective view of a display apparatus 1 according to some embodiments. FIGS. 2A and 2B are perspective views showing the display apparatus 1 of FIG. 1 stretched in a first direction. FIG. 2C is a perspective view showing the display apparatus 1 of FIG. 1 stretched in a second direction. FIG. 2D is a perspective view showing the display apparatus 1 of FIG. 1 stretched in the first direction and the second direction. FIG. 2E is a perspective view showing the display apparatus 1 of FIG. 1 stretched in a third direction.

Referring to FIG. 1, the display apparatus 1 may include a display area DA and a non-display area NDA. The display area DA may include a plurality of pixels (sub-pixels). The display apparatus 1 may provide a certain image by using light emitted from the plurality of pixels. The non-display area NDA may be a peripheral area (e.g., outside a footprint) of the display area DA and may be arranged outside the display area DA. The non-display area NDA may be an area in which pixels are not arranged. The non-display area NDA may entirely surround the display area DA.

The display apparatus 1 may be stretched (e.g., expanded) or shrunk (e.g., reduced in size) in various directions. The display apparatus 1 may be stretched in the first direction (for example, an x direction and/or a −x direction) by an external force applied by an external object or a user. According to some embodiments, as illustrated in FIGS. 2A and 2B, the display area DA and/or the non-display area NDA of the display apparatus 1 may be stretched in the first direction (for example, the x direction and/or the −x direction). For example, as illustrated in FIG. 2A, the display apparatus 1 may be stretched in the x direction and the −x direction, or as illustrated in FIG. 2B, the display apparatus 1 may be stretched in the x direction with a side of the display apparatus 1 fixed.

The display apparatus 1 may be stretched in the second direction (for example, a y direction and/or a −y direction) by an external force applied by an external object or a user. According to some embodiments, as illustrated in FIG. 2C, the display area DA and/or the non-display area NDA of the display apparatus 1 may be stretched in the y direction and the −y direction. According to some embodiments, the display apparatus 1 may be stretched in the y direction and the −y direction with a side of the display apparatus 1 fixed.

The display apparatus 1 may be stretched in a plurality of directions, for example, the first direction (for example, the x direction and/or the −x direction) and the second direction (for example, the y direction and/or the −y direction), by an external force applied by an external object or a part of a human body. As illustrated in FIG. 2D, the display area DA and/or the non-display area NDA of the display apparatus 1 may be stretched in the ±x directions and the ty directions.

The display apparatus 1 may be stretched in the third direction (for example, a z direction or a −z direction) by an external force applied by an external object or a part of a human body. According to some embodiments, FIG. 2E illustrates that a portion of the display apparatus 1, for example, a region of the display area DA, may protrude in the z direction. According to some embodiments, a portion of the display apparatus 1, for example, a region of the display area DA, may protrude in the −z direction (or may be recessed from the z direction).

FIGS. 2A to 2E illustrate that the display apparatus 1 may be stretched in the first direction, the second direction, and/or the third direction. However, embodiments according to the present disclosure are not limited thereto. According to some embodiments, the display apparatus 1 may be variously deformed to have amorphous shapes, such as a shape that is bent or twisted with respect to two or more axes, etc.

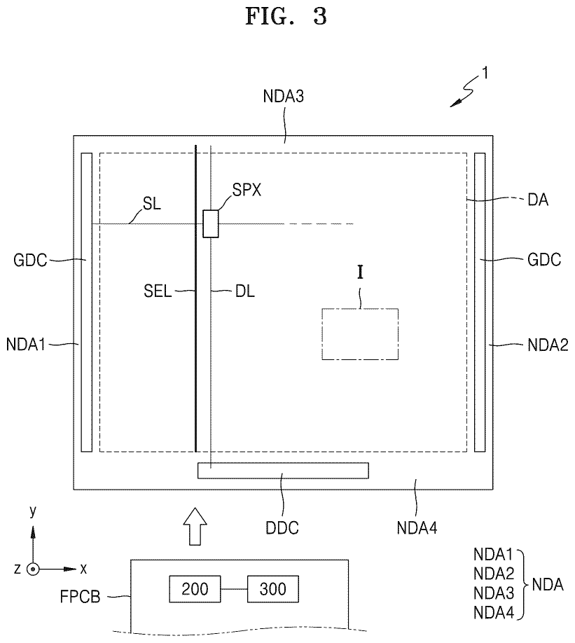

FIG. 3 is a schematic plan view of the display apparatus 1 according to some embodiments.

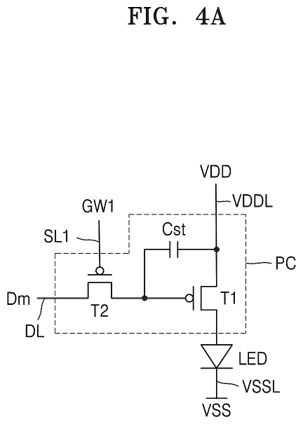

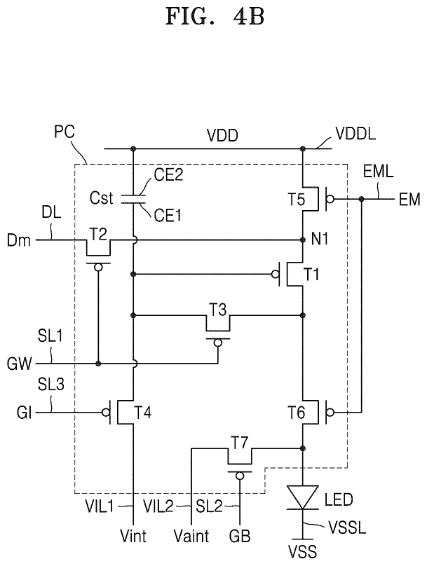

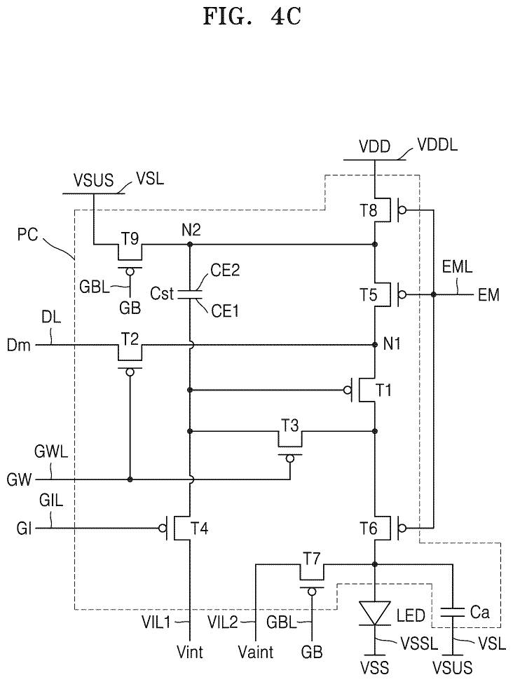

A plurality of pixels may be arranged in the display area DA of the display apparatus 1. Each pixel may include sub-pixels SPX emitting light of different colors. A light-emitting diode corresponding to each sub-pixel SPX may be arranged in the display area DA. The light-emitting diode may be driven by a pixel-driving circuit portion PC (see FIGS. 4A to 4C) arranged in the display area DA.

In the non-display area NDA around the display area DA, circuits configured to provide electrical signals to the pixel-driving circuit portions arranged in the display area DA may be placed. A gate driving circuit GDC may be arranged in each of a first non-display area NDA1 and a second non-display area NDA2 arranged at both sides of the display area DA, respectively. The gate driving circuit GDC may include drivers configured to provide an electrical signal to a gate electrode of each of transistors included in the pixel-driving circuit portion. The gate driving circuit GDC may be configured to transmit the electrical signal through a scan line SL. The scan line SL may extend in the x direction in the display area DA.

FIG. 3 illustrates that the gate driving circuit GDC may be arranged in each of the first non-display area NDA1 and the second non-display area NDA2. However, embodiments according to the present disclosure are not limited thereto. According to some embodiments, the gate driving circuit GDC may be arranged in any one of the first non-display area NDA1 and the second non-display area NDA2.

A data driving circuit DDC may be arranged in a third non-display area NDA3 and/or a fourth non-display area NDA4. According to some embodiments, FIG. 3 illustrates that the data driving circuit DDC may be arranged in the fourth non-display area NDA4. According to some embodiments, the data driving circuit DDC may be arranged in each of the third non-display area NDA3 and the fourth non-display area NDA4. The data driving circuit DDC may include drivers configured to provide electrical signals to the transistors included in the pixel-driving circuit portion. The data driving circuit DDC may be configured to transmit the electrical signals through a data line DL. The data line DL may extend in the y direction in the display area DA.

FIG. 3 illustrates that the data driving circuit DDC may be arranged in the fourth non-display area NDA4 of the display apparatus 1. However, the embodiments according to the present disclosure are not limited thereto. According to some embodiments, the display apparatus 1 may further include a flexible circuit board FPCB electrically connected to the display apparatus 1 through a terminal portion arranged in the fourth non-display area NDA4, and the data driving circuit DDC may be arranged on this flexible circuit board FPCB. Also, a sensing portion 200 and a correction control portion 300 may be arranged on the flexible circuit board FPCB. The sensing portion 200 may include a sensing circuit configured to sense a degree in which the display apparatus 1 is stretched. The correction control portion 300 may be configured to provide, based on a value sensed by the sensing portion 200, a signal for correcting arrangement of the pixels included in the display apparatus 1. Detailed operations of the sensing portion 200 and the correction control portion 300 are described below.

The display apparatus 1 according to some embodiments may be a stretchable display apparatus, and the display apparatus 1 may be stretchable in all positions or all portions thereof or may be stretchable in only certain positions or certain portions thereof according to cases. Also, the display apparatus 1 may be stretchable in all directions or may be stretchable in only certain directions. The degree in which the display apparatus 1 is stretched may be the same with respect to all positions, portions, and directions or may be different with respect to certain positions, portions, and directions.

According to some embodiments, a sensing line SEL may be included in the display area DA. The sensing line SEL may be provided to extend in the x direction and/or the y direction. For example, the sensing line SEL may be provided in parallel with the scan line SL or in parallel with the data line DL. Alternatively, the sensing line SEL may include a horizontal sensing line in parallel with the scan line SL and a vertical sensing line in parallel with the data line DL. Alternatively, the sensing line SEL may be provided as the scan line SL or the data line DL.

The sensing line SEL may be used to sense a degree by which the display apparatus 1 is stretched or shrunk. When the display apparatus 1 is stretched, the display apparatus 1 may be stretched by a varying degree according to a position and a portion thereof, and thus, the display apparatus 1 according to some embodiments may include the sensing line SEL for sensing the degree by which the display apparatus is stretched according to the position and the portion thereof. The degree by which the sensing line SEL is stretched may be measured from a resistance change, a capacitance change, and/or a waveform change with respect to an electrical signal, according to a position of the sensing line SEL. The change value with respect to the sensing line SEL may be transmitted to the sensing portion 200, and the deformation rate of the display apparatus 1 may be measured.

The display apparatus 1 According to some embodiments may be a stretchable display apparatus, and at least some elements included in the display apparatus 1 may have the stretchable characteristic. For example, all elements including a substrate, lines, electrodes, pixel-driving circuits, etc. arranged in the display area DA may have the stretchable characteristic, or only some elements may have the stretchable characteristic.

For example, the sensing line SEL may include a stretchable material, for example, a highly flexible metal material. According to some embodiments, the sensing line SEL may include liquid metal or a mixture of liquid metal and a rubber material. According to some embodiments, the sensing line SEL may include nanoparticles, nanoflakes, or nanowires of metal, silver, copper, etc. According to some embodiments, the sensing line SEL may include a mixture of a nanostructure including metal, silver, copper, etc. and a rubber material. Alternatively, the sensing line SEL may include a carbon nanotube or graphene. The sensing line SEL may include a mixture of a carbon-based nanostructure and a rubber material.

FIGS. 4A to 4C are each an equivalent circuit diagram of a sub-pixel of the display apparatus 1 according to some embodiments.

Referring to FIG. 4A, a light-emitting diode LED corresponding to the sub-pixel may be electrically connected to the pixel driving circuit portion PC, and the pixel driving circuit portion PC may include a first transistor T1, a second transistor T2, and a storage capacitor Cst. The pixel driving circuit portion PC may be electrically connected to a signal line and a voltage line. The signal line may include a gate line such as a first scan line SL1, and a data line DL, and the voltage line may include a first voltage line VDDL.

The second transistor T2 may be electrically connected to the first scan line SL1 and the data line DL. The first scan line SL1 may be configured to provide a first scan signal GW1 to a gate electrode of the second transistor T2. The second transistor T2 may be configured to transmit a data signal Dm input from the data line DL to the first transistor T1, according to the first scan signal GW1 input from the first scan line SL1.

The storage capacitor Cst may be electrically connected to the second transistor T2 and the first voltage line VDDL and may be configured to store a voltage corresponding to the difference between a voltage transmitted from the second transistor T2 and a first power voltage VDD supplied by the first voltage line VDDL.

The first transistor T1 may be a driving transistor and may be configured to control a driving current flowing through the light-emitting diode LED. The first transistor T1 may be connected to the first voltage line VDDL and the storage capacitor Cst. The first transistor T1 may be configured to control a driving current flowing from the first voltage line VDDL to the light-emitting diode LED according to a value of the voltage stored in the storage capacitor Cst. The light-emitting diode LED may emit light having a certain brightness according to the driving current. A first electrode of the light-emitting diode LED may be electrically connected to the first transistor T1, and a second electrode of the light-emitting diode LED may be electrically connected to a second voltage line VSSL configured to supply a second power voltage VSS.

FIG. 4A illustrates that the pixel driving circuit portion PC may include two transistors and one storage capacitor. However, according to some embodiments, the pixel driving circuit portion PC may include three or more transistors. In various embodiments, the pixel driving circuit portion PC may include additional components without departing from the spirt and scope of embodiments according to the present disclosure.

Referring to FIG. 4B, the pixel driving circuit portion PC may include a first transistor T1, a second transistor T2, a third transistor T3, a fourth transistor T4, a fifth transistor T5, a sixth transistor T6, a seventh transistor T7, and a storage capacitor Cst. Although FIG. 4B illustrates the pixel driving circuit portion PC includes various components, embodiments according to the present disclosure are not limited thereto, and according to some embodiments, the pixel driving circuit portion PC may include additional components or fewer components without departing from the spirit and scope of embodiments according to the present disclosure.

The pixel driving circuit portion PC may be electrically connected to signal lines and voltage lines. The signal lines may include a gate line, such as a first scan line SL1, a second scan line SL2, a third scan line SL3, a fourth scan line SL4, and an emission control line EML, and a data line DL. The voltage lines may include first and second initialization voltage lines VIL1 and VIL2 and a first voltage line VDDL.

The first voltage line VDDL may be configured to transmit a first power voltage VDD to the first transistor T1. The first initialization voltage line VIL1 may be configured to transmit a first initialization voltage Vint for initializing the first transistor T1 to the pixel driving circuit portion PC. The second initialization voltage line VIL2 may be configured to transmit a second initialization voltage Vaint for initializing a first electrode of the light-emitting diode LED to the pixel driving circuit portion PC.

The first transistor T1 may be electrically connected to the first voltage line VDDL through the fifth transistor T5 and may be electrically connected to the light-emitting diode LED through the sixth transistor T6. The first transistor T1 may function as a driving transistor and may be configured to receive a data signal Dm and transmit a driving current to the light-emitting diode LED according to a switching operation of the second transistor T2.

The second transistor T2 may be a data write transistor and may be electrically connected to the first scan line SL1 and the data line DL. The second transistor T2 may be electrically connected to the first voltage line VDDL through the fifth transistor T5. The second transistor T2 may be turned on according to a first scan signal GW transmitted through the first scan line SL1 and may be configured to perform a switching operation of transmitting the data signal Dm transmitted through the data line DL to a first node N1.

The third transistor T3 may be electrically connected to the first scan line SL1 and may be electrically connected to the light-emitting diode LED through the sixth transistor T6. The third transistor T3 may be turned on according to the first scan signal GW transmitted through the first scan line SL1 and may diode-connect the first transistor T1.

The fourth transistor T4 may be a first initialization transistor and may be electrically connected to the third scan line SL3 and the first initialization voltage line VIL1. The fourth transistor T4 may be turned on according to a third scan signal GI transmitted through the third scan line SL3 and may be configured to transmit the first initialization voltage Vint from the first initialization voltage line VIL1 to a gate electrode of the first transistor T1 to initialize a voltage of the gate electrode of the first transistor T1. The third scan signal GI may correspond to a first scan signal of a different pixel driving circuit portion arranged in a previous row of the corresponding pixel driving circuit portion PC.

The fifth transistor T5 may be an operation control transistor, and the sixth transistor T6 may be an emission control transistor. The fifth transistor T5 and the sixth transistor T6 may be electrically connected to the emission control line EML and may be simultaneously turned on according to an emission control signal EM transmitted through the emission control line EML to form a current path through which a driving current may flow from the first voltage line VDDL in a direction toward the light-emitting diode LED.

The seventh transistor T7 may be a second initialization transistor and may be electrically connected to the second scan line SL2, the second initialization voltage line VIL2, and the sixth transistor T6. The seventh transistor T7 may be turned on according to a second scan signal GB transmitted through the second scan line SL2 and may be configured to transmit the second initialization voltage Vaint from the second initialization voltage line VIL2 to the first electrode of the light-emitting diode LED to initialize the first electrode of the light-emitting diode LED.

The storage capacitor Cst may include a first electrode CE1 and the second electrode CE2. The first electrode CE1 may be electrically connected to the gate electrode of the first transistor T1, and the second electrode CE2 may be electrically connected to the first voltage line VDDL. The storage capacitor Cst may be configured to store and sustain a voltage corresponding to the difference between a voltage of the first voltage line VDDL and a voltage of the gate electrode of the first transistor T1, so as to sustain a voltage applied to the gate electrode of the first transistor T1.

Referring to FIG. 4C, the pixel driving circuit portion PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca. Although FIG. 4C illustrates the pixel driving circuit portion PC includes various components, embodiments according to the present disclosure are not limited thereto, and according to some embodiments, the pixel driving circuit portion PC may include additional components or fewer components without departing from the spirit and scope of embodiments according to the present disclosure.

The pixel driving circuit portion PC may be electrically connected to signal lines and voltage lines. The signal lines may include a gate line, such as a first scan line SL1, a second scan line SL2, a third scan line SL3, a fourth scan line SL4, and an emission control line EML, and a data line DL. The voltage lines may include first and second initialization voltage lines VIL1 and VIL2, a sustaining voltage line VSL, and a first voltage line VDDL.

The first voltage line VDDL may be configured to transmit a first power voltage VDD to the first transistor T1. The first initialization voltage line VIL1 may be configured to transmit a first initialization voltage Vint for initializing the first transistor T1 to the pixel driving circuit portion PC. The second initialization voltage line VIL2 may be configured to transmit a second initialization voltage Vaint for initializing a first electrode of the light-emitting diode LED to the pixel driving circuit portion PC. The sustaining voltage line VSL may be configured to provide a sustaining voltage VSUS to a second node N2, for example, a second electrode CE2 of the storage capacitor Cst, in an initialization section and a data write section.

The first transistor T1 may be electrically connected to the first voltage line VDDL through the fifth transistor T5 and the eighth transistor T8 and may be electrically connected to the light-emitting diode LED through the sixth transistor T6. The first transistor T1 may function as a driving transistor and may be configured to receive a data signal Dm and transmit a driving current to the light-emitting diode LED according to a switching operation of the second transistor T2.

The second transistor T2 may be electrically connected to the first scan line SL1 and the data line DL and may be electrically connected to the first voltage line VDDL through the fifth transistor T5 and the eighth transistor T8. The second transistor T2 may be turned on according to a first scan signal GW transmitted through the first scan line SL1 and may be configured to perform a switching operation of transmitting the data signal Dm transmitted through the data line DL to a first node N1.

The third transistor T3 may be electrically connected to the first scan line SL1 and may be electrically connected to the light-emitting diode LED through the sixth transistor T6. The third transistor T3 may be turned on according to the first scan signal GW transmitted through the first scan line SL1 and may be configured to diode-connect the first transistor T1 to compensate for a threshold voltage of the first transistor T1.

The fourth transistor T4 may be electrically connected to the third scan line SL3 and the first initialization voltage line VIL1 and may be turned on according to a third scan signal GI transmitted through the third scan line SL3 and may be configured to transmit the first initialization voltage Vint from the first initialization voltage line VIL1 to a gate electrode of the first transistor T1 to initialize a voltage of the gate electrode of the first transistor T1. The third scan signal GI may correspond to a first scan signal of a different pixel driving circuit portion arranged in a previous row of the corresponding pixel driving circuit portion PC.

The fifth transistor T5, the sixth transistor T6, and the eighth transistor T8 may be electrically connected to the emission control line EML and may be simultaneously turned on according to an emission control signal EM transmitted through the emission control line EML to form a current path through which a driving current may flow from the first voltage line VDDL in a direction toward the light-emitting diode LED.

The seventh transistor T7 may be a second initialization transistor and may be electrically connected to the second scan line SL2, the second initialization voltage line VIL2, and the sixth transistor T6. The seventh transistor T7 may be turned on according to a second scan signal GB transmitted through the second scan line SL2 and may be configured to transmit the second initialization voltage Vaint from the second initialization voltage line VIL2 to the first electrode of the light-emitting diode LED to initialize the first electrode of the light-emitting diode LED.

The ninth transistor T9 may be electrically connected to the second scan line SL2, the second electrode CE2 of the storage capacitor Cst, and the sustaining voltage line VSL. The ninth transistor T9 may be turned on according to the second scan signal GB transmitted through the second scan line SL2 and may be configured to transmit the sustaining voltage VSUS to a second node N2, for example, the second electrode CE2 of the storage capacitor Cst, in an initialization section and a data write section.

Each of the eighth transistor T8 and the ninth transistor T9 may be electrically connected to the second node N2, for example, the second electrode CE2 of the storage capacitor Cst. According to some embodiments, in the initialization section and the data write section, the eighth transistor T8 may be turned off and the ninth transistor T9 may be turned on, and in the emission section, the eighth transistor T8 may be turned on and the ninth transistor T9 may be turned off. The sustaining voltage VSUS may be transmitted to the second node N2 in the initialization section and the data write section, and thus, the uniformity of the brightness (for example, the long range uniformity (LRU)) of the display apparatus according to a voltage drop of the first voltage line VDDL may be improved.

The storage capacitor Cst may include a first electrode CE1 and the second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the sustaining voltage line VSL, and the first electrode of the light-emitting diode LED. The auxiliary capacitor Ca may be configured to store and sustain a voltage corresponding to the difference between voltages of the first electrode of the light-emitting diode LED and the sustaining voltage line VSL, while the seventh transistor T7 and the ninth transistor T9 are being turned on, and thus, the auxiliary capacitor Ca may prevent an increase in black brightness when the sixth transistor T6 is turned off.

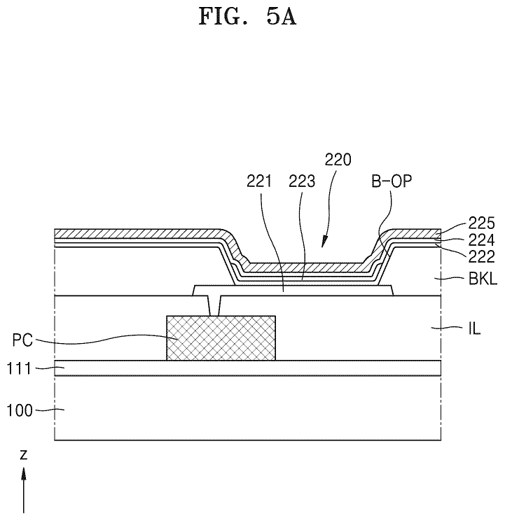

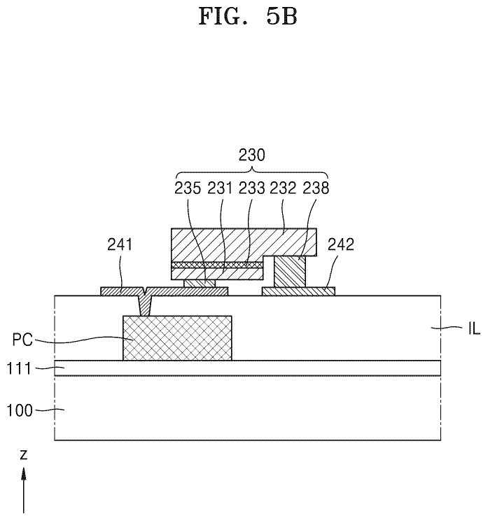

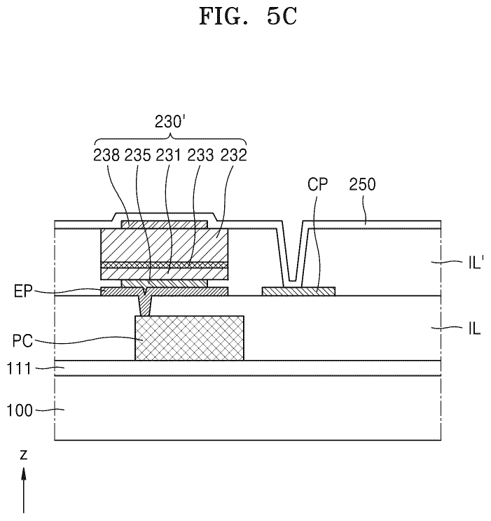

FIGS. 5A to 5C are schematic cross-sectional views of a portion of a display area applicable to a display apparatus according to embodiments. In detail, FIGS. 5A to 5C are schematic cross-sectional views of a light-emitting diode which may be included in the display area.

Referring to FIGS. 5A to 5C, the display apparatus may include a substrate 100, a pixel driving circuit portion PC, and a light-emitting diode connected to the pixel driving circuit portion PC.

The substrate 100 may include polymer resins, such as polyether sulfone, polyarylate, polyether imide, polyethylene naphthalate, polyethylene terephthalate, polyphenylene sulfide, polyimide, polycarbonate, cellulose triacetate, and cellulose acetate propionate. According to some embodiments, the substrate 100 may include a single layer including the polymer resins described above. According to some embodiments, the substrate 100 may have a multi-layered structure including a base layer including the polymer resins described above and a barrier layer including an inorganic insulating material. The substrate 100 including the polymer resins may be flexible, rollable, or bendable.

A buffer layer 111 may be located on the substrate 100. The buffer layer 111 may include an inorganic insulating material. For example, the buffer layer 111 may include silicon oxide, silicon nitride, and/or silicon oxynitride. The pixel driving circuit portion PC may be located on the buffer layer 111. A lower insulating layer IL including an inorganic insulating material and/or an organic insulating material may be located between the pixel driving circuit portion PC and the light-emitting diode. The light-emitting diode may be located on the lower insulating layer IL and may be electrically connected to the corresponding pixel driving circuit portion PC. The light-emitting diodes may emit light of different colors or light of the same color. According to some embodiments, the light-emitting diodes may emit red, green, and blue light, respectively. According to some embodiments, the light-emitting diodes may emit white light. According to some embodiments, the light-emitting diodes may emit red, green, blue, and white light, respectively.

Referring to FIG. 5A, the light-emitting diode according to some embodiments may include an organic light-emitting diode 220 including an organic material. The organic light-emitting diode 220 may include a first electrode 221 located on an insulating layer, a second electrode 225 facing the first electrode 221, and an emission layer 223 located between the first electrode 221 and the second electrode 225. A first functional layer 222 may be located between the first electrode 221 and the emission layer 223, and a second functional layer 224 may be located between the emission layer 223 and the second electrode 225.

An edge of the first electrode 221 may be covered by a bank layer BKL including an insulating material. The bank layer BKL may include an opening B-OP overlapping a central portion of the first electrode 221.

The first electrode 221 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to some embodiments, the first electrode 221 may include a reflective layer including Ag, Mg, Al, Pt, Pd, Au, Ni, Nd, Ir, Cr, or a compound thereof. According to some embodiments, the first electrode 221 may further include a layer including ITO, IZO, ZnO, AZO or In₂O₃ above/below the reflective layer described above.

The emission layer 223 may include a high molecular-weight or a low molecular-weight organic material emitting light of a certain color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. For example, the second electrode 225 may include a transparent (semi-transparent) layer including Ag, Mg, Al, Pt, Pd, Au, Ni, Nd, Ir, Cr, Li, Ca, or an alloy thereof. Alternatively, the second electrode 225 may further include a layer, such as ITO, IZO, ZnO, AZO, or In₂O₃, on the transparent (semi-transparent) layer including the material described above.

Referring to FIG. 5B, the light-emitting diode according to some embodiments may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232.

The first electrode 235 and the second electrode 238 of the inorganic light-emitting diode 230 may be arranged toward the same direction. Both of the first electrode 235 and the second electrode 238 may be located below the intermediate layer 233. Thus, the first electrode 235 and the second electrode 238 of the inorganic light-emitting diode 230 of FIG. 5B may be directly connected to an electrode pad EP and a common electrode pad CP, respectively, which are located on the same layer.

According to some embodiments, the first semiconductor layer 231 may include a p-type semiconductor layer. The p-type semiconductor layer may include a semiconductor material having a composition of InₓAl_{y}Ga_{1-x-y}N (0≤x≤1, 0≤y≤1, and 0≤x+y≤1), for example, a material selected from among GaN, AlN, AlGaN, InGaN, InN, InAlGaN, AlInN, and the like, and may be doped with a p-type dopant, such as Mg, Zn, Ca, Sr, Ba, and the like.

The second semiconductor layer 232 may include, for example, an n-type semiconductor layer. The n-type semiconductor layer may include a semiconductor material having a composition of InₓAl_{y}Ga_{1-x-y}N (0≤x≤1, 0≤y≤1, and 0≤x+y≤1), for example, a material selected from among GaN, AlN, AlGaN, InGaN, InN, InAlGaN, AlInN, and the like, and may be doped with an n-type dopant, such as Si, Ge, Sn, and the like.

The intermediate layer 233 may be where electrons and holes reunite, and

when the electrons and the holes reunite, transition to a reduced energy level may be performed to generate light having a wavelength corresponding to the reduced energy level. The intermediate layer 233 may include, for example, a semiconductor material having a composition of InₓAl_{y}Ga_{1-x-y}N (0≤x≤1, 0≤y≤1, and 0≤x+y≤1) and may be formed as a single quantum well structure or a multi-quantum well (MQW) structure. Also, the intermediate layer 233 may include a quantum wire structure or a quantum dot structure.

It is described with reference to FIG. 5B that the first semiconductor layer 231 may include the p-type semiconductor layer and the second semiconductor layer 232 may include the n-type semiconductor layer. However, embodiments according to the present disclosure are not limited thereto. According to some embodiments, the first semiconductor layer 231 may include the n-type semiconductor layer, and the second semiconductor layer 232 may include the p-type semiconductor layer.

FIG. 5C is a schematic cross-sectional view of the light-emitting diode of the display apparatus according to some embodiments. In FIGS. 5C and 5B, like reference numerals refer to like members.

Referring to FIG. 5C, the light-emitting diode according to some embodiments may include an inorganic light-emitting diode 230′ including an inorganic material. The inorganic light-emitting diode 230′ may include the first semiconductor layer 231, the second semiconductor layer 232, the intermediate layer 233 between the first semiconductor layer 231 and the second semiconductor layer 232, the first electrode 235 electrically connected to the first semiconductor layer 231, and the second electrode 238 electrically connected to the second semiconductor layer 232.

The first electrode 235 and the second electrode 238 of the inorganic light-emitting diode 230′ may be electrically connected to the electrode pad EP and the common electrode pad CP, respectively, which are located on the same layer.

The first electrode 235 and the second electrode 238 of the inorganic light-emitting diode 230′ of FIG. 5C may be arranged toward different directions. The first electrode 235 may be located below the intermediate layer 233 and the second electrode 238 may be located above the intermediate layer 233. The second electrode 238 may be electrically connected to the common electrode pad CP through a common electrode 250.

An upper insulating layer IL′ may be located between the common electrode

pad CP and the common electrode 250. The upper insulating layer IL′ may cover the inorganic light-emitting diode 230′, while exposing the second electrode 238 of the inorganic light-emitting diode 230′. The common electrode 250 may be located on the upper insulating layer IL′ and may be directly connected to the second electrode 238. A contact hole exposing the common electrode pad CP may be provided in the upper insulating layer IL′. The common electrode 250 may be connected to the common electrode pad CP through the contact hole. The second electrode 238 may be electrically connected to the common electrode pad CP through the common electrode 250.

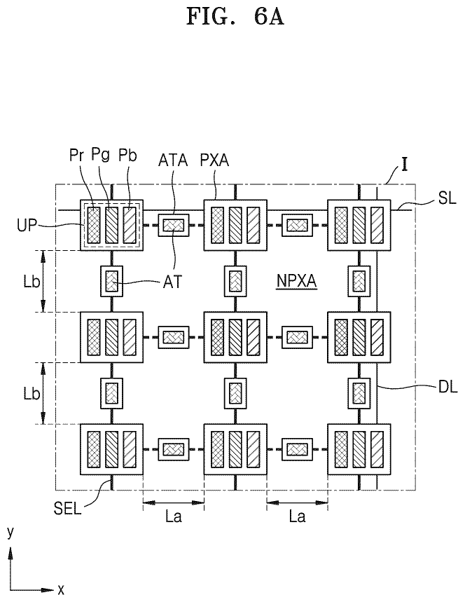

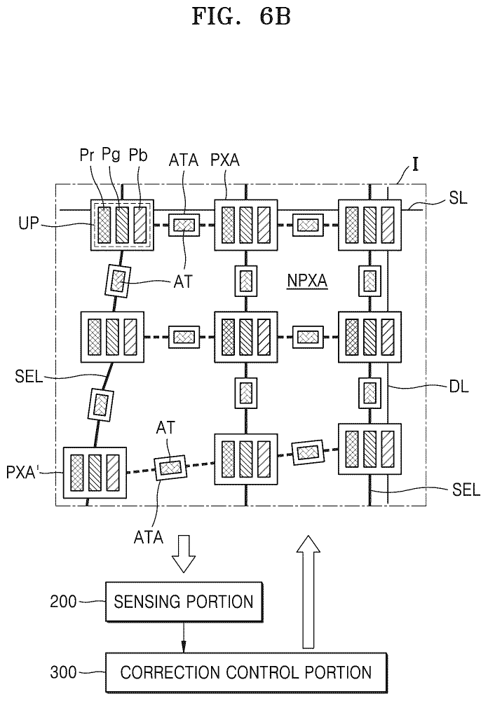

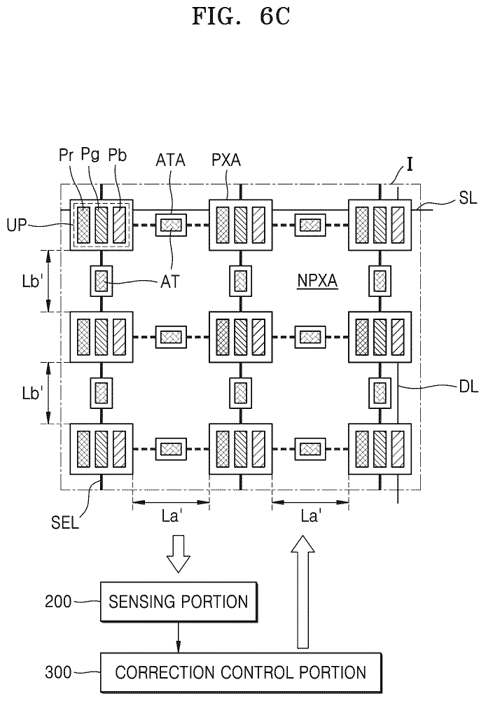

FIG. 6A is a schematic enlarged plan view of a portion of a display apparatus, the portion corresponding to region I of FIG. 3, according to some embodiments.

Referring to FIG. 6A, a display area of the display apparatus according to some embodiments may include a plurality of pixel areas PXA and a non-pixel area NPXA surrounding each of the plurality of pixel areas PXA.

The plurality of pixel areas PXA may be arranged in an x direction and a y direction. A distance between the pixel areas PXA adjacent to each other in the x direction may be constant as a first distance La. A distance between the pixel areas PXA adjacent to each other in the y direction may be constant as a second distance Lb.

At least one sub-pixel may be arranged in the pixel area PXA. The sub-pixel may include a red pixel Pr, a green pixel Pg, or a blue pixel Pb. A unit pixel UP including a set of the sub-pixels may be provided in the pixel area PXA. The unit pixel

UP may include the red pixel Pr, the green pixel Pg, and the blue pixel Pb. The sub-pixels may be realized by light-emitting diodes.

In FIG. 6A, the red pixel Pr, the green pixel Pg, and the blue pixel Pb included in the unit pixel UP may be arranged as a stripe structure in which the red pixel Pr, the green pixel Pg, and the blue pixel Pb are arranged in a direction. However, embodiments according to the present disclosure are not limited thereto. The sub-pixels SPX included in the unit pixel UP may be arranged as various structures including a diamond structure, a pentile™ structure, a mosaic structure, etc.

The pixel area PXA may have a greater modulus than the non-pixel area NPXA around the pixel area PXA. Accordingly, when the display apparatus is stretched, the pixel area PXA may be less deformed than the non-pixel area NPXA. The pixel area PXA may be referred to as an island portion or a low deformation portion. Also, the light-emitting diodes may be arranged in the pixel area PXA, which may be referred to as an emission area.

The non-pixel area NPXA may be arranged to surround the pixel area PXA and may have a less modulus than the pixel area PXA. The non-pixel area NPXA may be where main deformation occurs as the display apparatus is stretched. The non-pixel area NPXA may be arranged between the plurality of pixel areas PXA, and thus, may be referred to as a connection portion or a bridge portion that connects the pixel areas PXA. Also, the non-pixel area NPXA may be referred to as a main deformation portion or a high deformation portion. The light-emitting diodes may not be arranged in the non-display area NPXA of the display area, and the non-display area NPXA may be referred to as a non-emission area.

Lines and an actuator area ATA may be arranged in the non-pixel area NPXA. The lines may be configured to transmit various signals for driving the sub-pixels arranged in the pixel area PXA. For example, a scan line SL may be configured to transmit a scan signal to a pixel circuit configured to drive the sub-pixels and may extend in the x direction. A data line DL may be configured to transmit a data signal to the pixel circuit configured to drive the sub-pixels and may extend in the y direction. In FIG. 6A, for brevity of the drawing, only one scan line SL and only one data line DL are illustrated, and the other scan lines SL and data lines DL are omitted.

Also, some of the lines may be configured to transmit a driving signal to the actuator area ATA. A sensing line SEL from among the lines may be arranged across the pixel area PXA. A deformation rate of each pixel area PXA according to a position may be measured based on the sensing line SEL. In this specification, a deformation rate indicates a degree in which a substrate or a display apparatus is stretched or shrunk, in comparison with an initially set reference value. The sensing line SEL may be coupled to the elements of the display apparatus, and thus, based on the degree in which the sensing line SEL is stretched, the degree in which the display apparatus is stretched may be measured.

The actuator area ATA may be arranged between the plurality of pixel areas PXA. The pixel area PXA and the actuator area ATA may be alternately arranged in the x direction. Also, the pixel area PXA and the actuator area ATA may be alternately arranged in the y direction.

The actuator area ATA may be provided for a correction operation for arranging the pixel area PXA in a desired location. The actuator area ATA may include at least one actuator AT. The actuator AT may be coupled to the elements of the display apparatus and may be configured to physically stretch or shrink the non-pixel area NPXA according to a driving signal. The actuator AT may include a soft actuator and may be configured to perform a reversible motion in response to a change of an electrical signal, heat, light, etc. According to some embodiments, the actuator AT may include a dielectric elastomer actuator (DEA) a polymer actuator, a piezoelectric actuator, and/or an electro-active polymer actuator (EAP).

FIGS. 6B and 6C are schematic plan views to describe an operation when deformation occurs in a display apparatus according to the present application. In FIGS. 6B and 6C, like reference numerals as in FIG. 6A refer to like elements as in FIG. 6A.

Referring to FIGS. 6B and 6C, the display apparatus according to some embodiments may include the sensing portion 200 configured to sense a deformation rate of the display apparatus according to a change of a measurement value of the sensing line SEL and the correction control portion 300 configured to provide a correction signal based on the deformation rate sensed by the sensing portion 200.

FIG. 6B shows an early stage of deformation of the display apparatus. The display apparatus according to some embodiments may be stretchable, and thus, may be deformed by an external force. In this case, at the early stage of deformation, undesired deformation may occur. For example, while the display apparatus is being stretched, a pixel area may be dislocated, as a pixel area PXA′ arranged at the lower left end in FIG. 6B.

Like this, when undesired deformation, for example, non-uniform local deformation, occurs, the sensing portion 200 may sense the portion in which the non-uniform deformation occurs, through the sensing line SEL, and, based on the sensing value of the sensing portion 200, the correction control portion 300 may apply a driving signal to the actuator AT included in the actuator area ATA. According to the driving signal of the correction control portion 300, the actuator AT arranged in the actuator area ATA may physically move so that all pixel areas PXA may be arranged in desired locations.

Based on this operation, when the plurality of pixel areas PXA are set to be uniformly arranged, all of the pixel areas PXA may be uniformly arranged likewise after the deformation, as illustrated in FIG. 6C. That is, after the correction, the plurality of pixel areas PXA may be arranged in the x direction and the y direction. A distance between the pixel area PXA adjacent to each other in the x direction may be provided to be constant as a third distance La′ which is greater than the first distance La. A distance between the pixel area PXA adjacent to each other in the y direction may be provided to be constant as a fourth distance Lb′, which is greater than the second distance Lb.

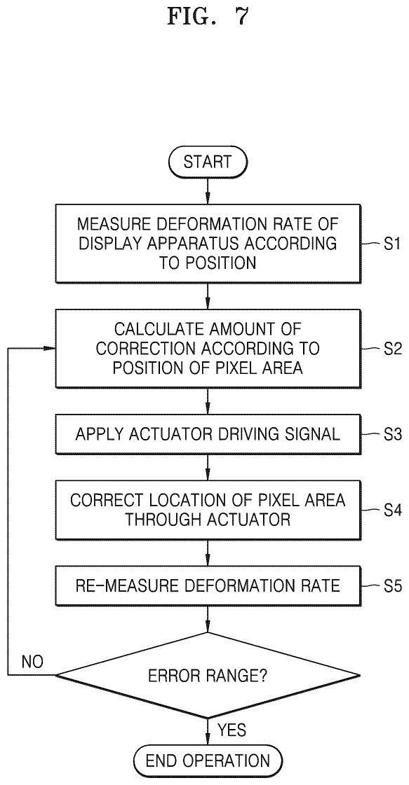

FIG. 7 is an example of a flowchart of a driving operation of a display apparatus, according to some embodiments.

First, a deformation rate according to a position of the display apparatus may be measured in operation S1. The deformation rate may be measured by the sensing portion 200 (see FIG. 6B). The sensing portion 200 may calculate the deformation rate of the display apparatus by measuring a resistance change, a capacitance change, and/or a waveform change with respect to an electrical signal, based on a position of the sensing line SEL (see FIG. 6B) arranged in a display area.

Next, the amount of correction based on the position of the pixel area may be calculated in operation S2. The amount of correction may be calculated by the correction control portion 300.

A value of the deformation rate measured by the sensing portion 200 may be transmitted to the correction control portion 300, and the correction control portion 300 may calculate an average deformation rate of a pre-set portion. The pre-set portion may be the whole or part of the display area. Next, the amount of correction may be set based on the difference between the deformation rate of each position and the average deformation rate.

Next, a driving signal may be applied to the actuator according to the amount of correction in operation S3. The driving signal applied to the actuator may be generated by the correction control portion 300. The driving signal may be a stretching signal or a shrinkage signal.

Next, the actuator receiving the driving signal may correct the location of the pixel area by performing a stretching operation or a shrinkage operation in operation S4.

Next, the sensing portion 200 may re-measure the deformation rate according to the position of the display apparatus in operation S5. When the re-measured deformation rate is within a pre-set error range, the correction operation may be ended. When the re-measured deformation rate is beyond the error range, the correction operation may be repeated by returning to operation S2.

The flowchart described above shows an operation to have the uniformly distributed pixel areas in a set area. However, embodiments according to the present disclosure are not limited thereto. The distribution of the pixel areas may be pre-set according to the degree of stretching, and the amount of correction may be calculated by taking into account the pre-set value and the deformation rate.

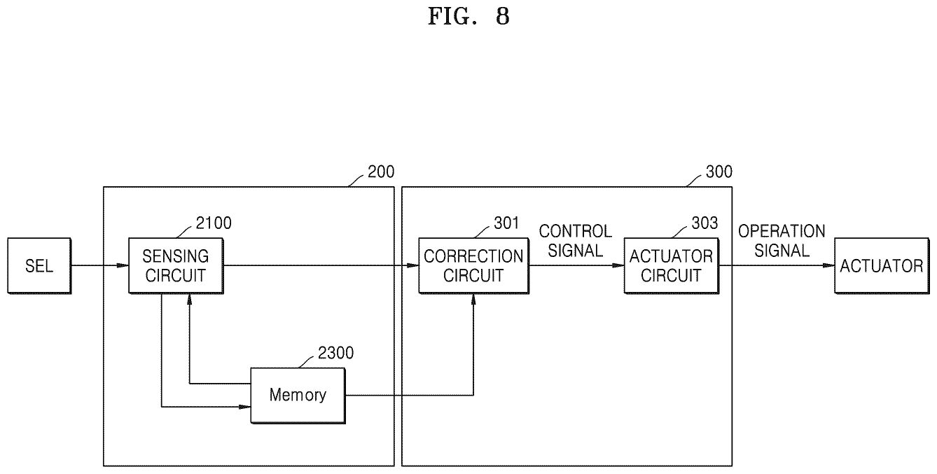

FIG. 8 is a schematic view of elements of the sensing portion 200 and the correction control portion 300 according to some embodiments.

The sensing portion 200 may include a sensing circuit 210 and a memory portion 2300. The correction control portion 300 may include a correction circuit 301 and an actuator circuit 303.

The sensing circuit 210 may measure the voltage, current, waveform, etc. applied to the sensing lines SEL. From the voltage, current, waveform, etc. measured as described above, a change of the resistance, capacitance, and waveform of the sensing lines SEL may be measured. The sensing circuit 210 may include a single component or a plurality of circuit components and may include an analog-to-digital converter, etc.

The sensing circuit 210 may sense all or part of the plurality of sensing lines SEL one by one according to an individual sensing method or, for sensing efficiency, may sense all or part of plurality of sensing line SEL by sensing each of groups including at least two of the all or part of the plurality of sensing lines SEL according to a group sensing method.

The memory portion 2300 may store a reference value of the characteristics of the sensing line SEL. For example, the memory portion 2300 may store the reference value of the resistance, capacitance, and/or waveform of the sensing line SEL. The memory portion 2300 may provide the reference value of the sensing line SEL to the sensing circuit 210.

The sensing circuit 210 may calculate a deformation rate of a display apparatus by comparing the reference value stored in the memory portion 2300 with the characteristics of the sensing line SEL after the display apparatus is deformed. Also, the sensing circuit 210 may transmit, based on the deformation rate, a correction value with respect to an initial deformation rate, to the memory portion 2300, and the memory portion 2300 may store the transmitted correction value. The sensing circuit 210 may sense the deformation rate with respect to all positions of a display area and may transmit the sensed deformation rate to the correction circuit 301 of the correction control portion 300.

The correction circuit 301 may calculate an average deformation rate of all pixel areas based on a deformation rate of the sensing line for each pixel area coordinate stored in the memory portion 2300. The correction circuit 301 may generate the correction value by comparing the average deformation rate of the plurality of pixel areas with the deformation rate of each pixel area.

The correction circuit 301 may apply a control signal to the actuator circuit 303 by taking into account the average deformation rate and the deformation rate, the deformation rate being received from the sensing circuit 210. The correction circuit 301 may compare the real time deformation rate received from the sensing circuit 210 with the average deformation rate, and when the difference therebetween deviates from an error range, may continually transmit the control signal to the actuator circuit 303. The correction circuit 301 may change the control signal or adjust output timing of the control signal.

The actuator circuit 303 may generate, based on the correction value transmitted from the correction circuit 301, a driving signal for driving the actuator, and may apply the driving signal to the actuator. When a stretching or shrinking degree of the actuator varies according to the voltage, the actuator circuit 303 may provide a voltage corresponding to a stretching or shrinking length of the actuator.

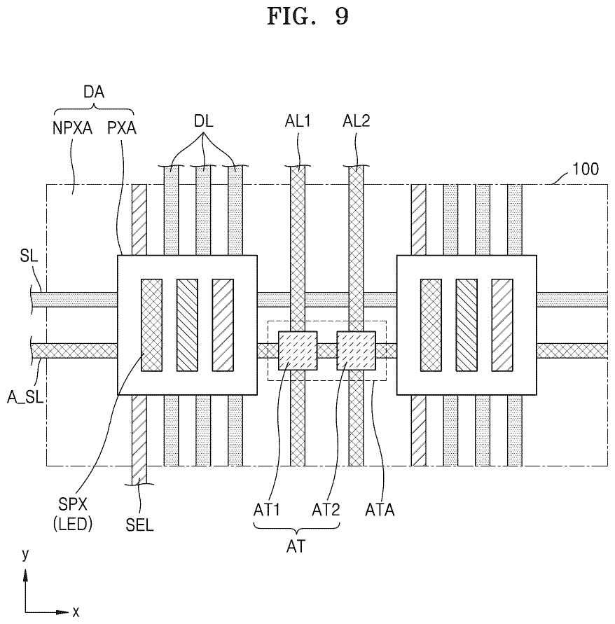

FIG. 9 is a schematic enlarged plan view of a portion of a display apparatus according to some embodiments. In FIG. 9, like reference numerals as in FIG. 6A refer to like elements in FIG. 6A.

Referring to FIG. 9, the display area DA of the display apparatus according to some embodiments may include the plurality of pixel areas PXA and the non-pixel area NPXA arranged between the plurality of pixel areas PXA. At least one light-emitting diode LED may be arranged in each of the plurality of pixel areas PXA, and a sub-pixel SPX may be realized by an emission area of the light-emitting diode LED. The non-pixel area NPXA may include the actuator area ATA, and at least one actuator AT may be arranged in the actuator area ATA. A modulus of the non-pixel area NPXA may be less than a modulus of the pixel area PXA. Thus, when the display apparatus is stretched, a deformation rate of the non-display area NPXA may be greater than a deformation rate of the pixel area PXA.

The sensing line SEL may be arranged across the plurality of pixel areas PXA, and according to a stretching degree of the sensing line SEL, the deformation rate of the display apparatus may be sensed according to the position of each pixel area PXA. The sensing line SEL may be connected to the sensing portion 200 (see FIG. 8) and may provide a characteristic change value of the sensing line SEL to the sensing portion 200. The stretching degree of the sensing line SEL may be measured from the resistance change, the capacitance change, and/or the waveform change with respect to an electrical signal, according to the position of the sensing line SEL.

The sensing portion 200 may provide the deformation rate measured through the sensing line SEL to the correction control portion 300 (see FIG. 8), and the correction control portion 300 may provide, based on the deformation rate, a driving signal for driving the actuator AT to the actuator AT.

Various lines may be arranged on the substrate 100. FIG. 9 illustrates only some of the lines. A scan line SL and an actuator scan line A_SL may be provided to extend in the x direction. The scan line SL may be configured to transmit a gate signal to a thin-film transistor included in the pixel driving circuit portion PC (see FIG. 4A, etc.). Also, the scan line SL may perform a function of a sensing line for sensing a position in the x direction. The actuator scan line A_SL may be connected to the actuator AT and may be configured to transmit a first driving signal to the actuator AT.

The sensing line SEL may extend in the y direction and may be arranged to cross the pixel area PXA. With respect to an area at which the scan line SL and the sensing line SEL cross each other, the characteristic change value of the sensing line SEL may be measured, in order to measure a deformation rate of the pixel area PXA. A data line DL may extend in the y direction and may be configured to provide a data signal to the pixel driving circuit portion PC arranged in the pixel area PXA. The number of data lines DL arranged to cross the pixel area PXA may be determined according to the number of sub-pixels SPX arranged in the pixel area PXA. In FIG. 9, three sub-pixels SPX may be arranged in the pixel area PXA, and thus, three data lines DL may be arranged to cross the pixel area PXA.

A first actuator AT1 and a second actuator AT2 may be arranged in parallel with each other between two adjacent pixel areas PXA. The first actuator AT1 may be a stretching actuator and the second actuator AT2 may be a shrinkage actuator.

The first actuator AT1 may be connected to a first driving signal line AL1 extending in the y direction. The first driving signal line AL1 may be configured to transmit a stretching driving signal. The second actuator AT2 may be connected to a second driving signal line AL2 extending in the y direction. The second driving signal line AL2 may be configured to transmit a shrinkage driving signal.

FIG. 9 illustrates that two actuators AT are provided between the two adjacent pixel areas PXA. However, embodiments according to the present disclosure are not limited thereto. Only one actuator AT or three or more actuators AT may be provided between the two pixel areas PXA. Like this, various modifications are possible.

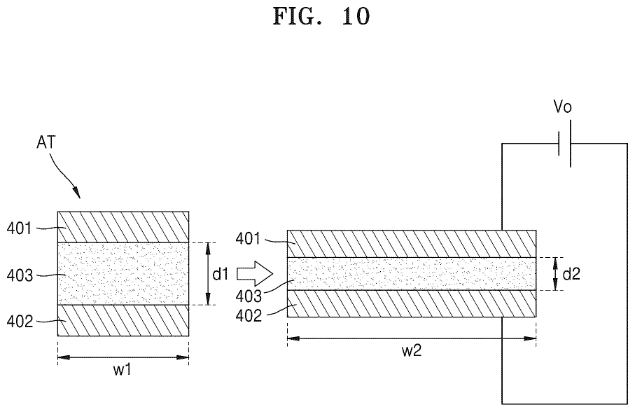

FIG. 10 is a view of an example of the applicable actuator AT, according to some embodiments.

Referring to FIG. 10, the actuator AT may be a DEA. The actuator AT1 may include a first electrode layer 401, a second electrode layer 402, and an elastomer layer 403 located between the first electrode layer 401 and the second electrode layer 402. The first electrode layer 401 and the second electrode layer 402 may include a metal layer including copper, etc. or a highly electrically conductive layer including a conductive polymer, a conductive carbon allotrope (or a carbon-based conductive mixture), etc. The first electrode layer 401 and the second electrode layer 402 may be provided to have a flat plate shape and may be arranged to face each other in parallel with each other. The elastomer layer 430 may include a dielectric elastomer. The elastomer layer 430 may include a flexible material, such as acryl-based or silicon-based resins.

When a voltage V0 is applied between the first electrode layer 401 and the second electrode layer 402, due to electrostatic attraction, a distance between the first electrode layer 401 and the second electrode layer 402 may become reduced from a first distance d1 to a second distance d2 which is less than the first distance d1 and the elastomer layer 403 may be extended, together with the first electrode layer 401 and the second electrode layer 402, in a surface direction of the first electrode layer 401 and the second electrode layer 402, to have a second width w2 from a first width w1.

The second distance d2 to which the elastomer layer 403 is reduced and the second width w2 to which the elastomer layer 403 is extended may vary according to a magnitude of the voltage V0. The elastomer layer 403 may be reduced in a direction in which the first electrode layer 401 and the second electrode layer 402 face each other and may be extended in a direction in which the first electrode layer 401 and the second electrode layer 402 are parallel with each other, and thus, according to a direction in which the actuator AT is arranged, the actuator AT may be a shrinkage actuator or a stretching actuator.

FIG. 10 illustrates that the actuator AT includes one elastomer layer. However, the actuator AT may include a plurality of elastomer layers between the first electrode layer 401 and the second electrode layer 402. For example, the actuator AT may include a stack of the first electrode layer 401/an elastomer layer/a conductive layer/an elastomer layer/the second electrode layer 402.

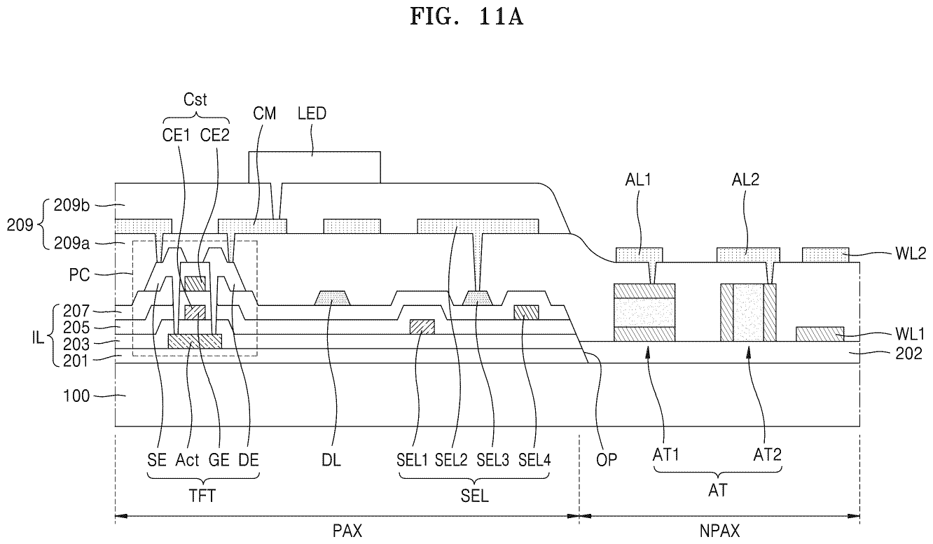

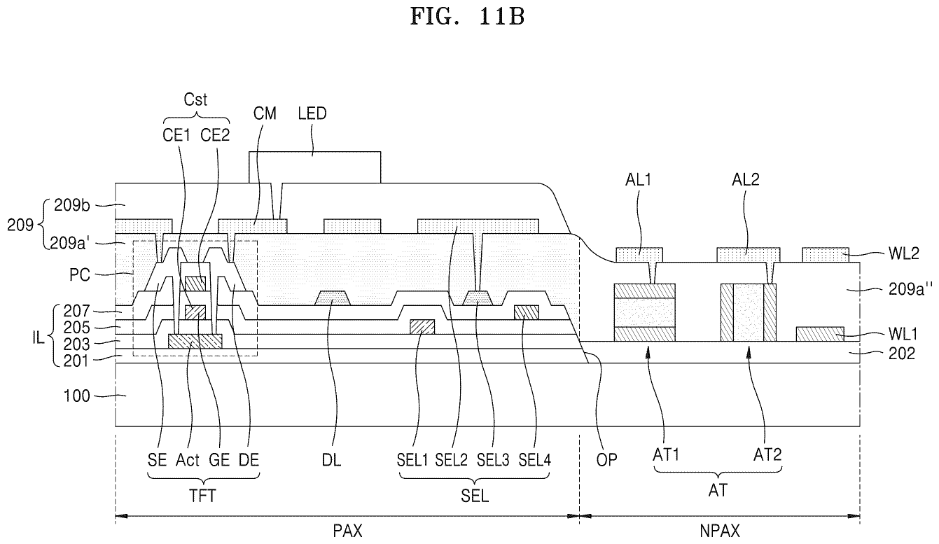

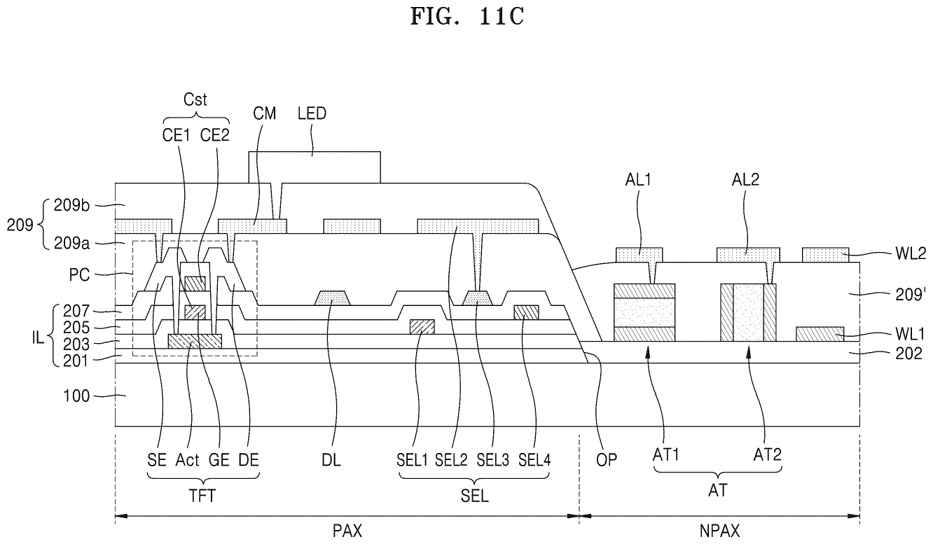

FIGS. 11A to 11C are schematic cross-sectional views of a portion of a display apparatus according to embodiments.

Referring to FIG. 11A, the display area DA of the display apparatus according to some embodiments may include the pixel area PXA and the non-pixel area NPAX. The pixel driving circuit portion PC and the light-emitting diode LED may be arranged in the pixel area PXA, and the actuator AT may be arranged in the non-pixel area NPXA. The pixel driving circuit portion PC may include at least one thin-film transistor TFT and a storage capacitor Cst.

First, elements arranged in the pixel area PXA are described according to a stacked order.

The substrate 100 may include a flexible material. For example, the substrate 100 may include a bendable, curved, foldable, or rollable material. The substrate 100 may include polymer resins, such as polyether sulfone, polyarylate, polyether imide, polyethylene naphthalate, polyethylene terephthalate, polyphenylene sulfide, polyimide, polycarbonate, cellulose triacetate, and cellulose acetate propionate. According to some embodiments, the substrate 100 may include a single layer including the polymer resins described above. According to some embodiments, the substrate 100 may have a structure of layers including a base layer including the polymer resins described above and a barrier layer including an inorganic insulating material.

A buffer layer 201 for preventing the penetration of impurities into a semiconductor layer Act of the thin-film transistor TFT may be formed in the pixel area PXA of the substrate 100. The buffer layer 201 may include an inorganic insulating material, such as silicon oxide, silicon nitride, and silicon oxynitride, and may include a single layer or layers including the inorganic insulating material described above.

The pixel driving circuit portion PC may be located on the buffer layer 201. The pixel driving circuit portion PC may include the thin-film transistor TFT and the storage capacitor Cst. The thin-film transistor TFT may include the semiconductor layer Act, a gate electrode GE, a source electrode SE, and a drain electrode DE. According to some embodiments, it is illustrated that the thin-film transistor TFT may be a top-gate type in which the gate electrode GE is located on the semiconductor layer Act with a gate insulating layer 203 therebetween. However, according to some embodiments, the thin-film transistor TFT may be a bottom-gate type.

The semiconductor layer Act may include polysilicon. Alternatively, the semiconductor layer Act may include amorphous silicon, an oxide semiconductor, or an organic semiconductor. The gate electrode GE may include a low-resistance metal material. The gate electrode GE may include a conductive material including Mo, Al, Cu, Ti, etc. and may include layers or a single layer including the conductive materials described above.

The gate insulating layer 203 between the semiconductor layer Act and the gate electrode GE may include an inorganic insulating material, such as SiOₓ, SiNₓ, SiON, aluminum oxide, titanium oxide, tantalum oxide, and hafnium oxide. The gate insulating layer 203 may include a single layer or layers including the materials described above.

The source electrode SE and the drain electrode DE may include a highly conductive material. The source electrode SE and the drain electrode DE may include a conductive material including Mo, Al, Cu, Ti, etc. and may include layers or a single layer including the materials described above. According to some embodiments, the source electrode SE and the drain electrode DE may include Ti/Al/Ti layers.

Also, the source electrode SE and the drain electrode DE may include a stretchable material. For example, the source electrode SE and the drain electrode DE may include liquid metal or a mixture of liquid crystal and a rubber material. Alternatively, the source electrode SE and the drain electrode DE may include nanoparticles, nanoflakes, or nanowires of metal, silver, copper, etc. According to some embodiments, the source electrode SE and the drain electrode DE may include a mixture of a nanostructure including metal, silver, copper, etc. and a rubber material. Alternatively, the source electrode SE and the drain electrode DE may include a carbon nanotube or graphene. Alternatively, the source electrode SE and the drain electrode DE may include a mixture of a carbon-based nanostructure and a rubber material.

The storage capacitor Cst may include a lower electrode CE1 and an upper electrode CE2 overlapping each other with a first interlayer insulating layer 205 therebetween. The storage capacitor Cst may overlap the thin-film transistor TFT. With respect to this aspect, FIG. 11A illustrates that the gate electrode GE of the thin-film transistor TFT may correspond to the lower electrode CE1 of the storage capacitor Cst. According to some embodiments, the storage capacitor Cst may not overlap the thin-film transistor TFT. The storage capacitor Cst may be covered by a second interlayer insulating layer 207.

The first and second interlayer insulating layers 205 and 207 may include an inorganic insulating material, such as SiOₓ, SiNₓ, SiON, aluminum oxide, titanium oxide, tantalum oxide, hafnium oxide, etc. The first and second interlayer insulating layers 205 and 207 may each include a single layer or layers including the materials described above. A data line DL may be located on the second interlayer insulating layer 207. The data line DL may include the same material as the source electrode SE and the drain electrode DE.

The pixel driving circuit portion PC including the thin-film transistor TFT and the storage capacitor Cst may be covered by a planarization layer 209. The planarization layer 209 may include an organic insulating material, such as a general-purpose polymer such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof. According to some embodiments, the planarization layer 209 may include polyimide.

According to some embodiments, the planarization layer 209 may include a structure in which a first planarization layer 209a and a second planarization layer 209b are stacked. Because the planarization layer 209 may have the structure in which the first planarization layer 209a and the second planarization layer 209b are stacked, a conductive layer, such as a connection electrode CM, may be located between the first planarization layer 209a and the second planarization layer 209b, to realize high integration.

The connection electrode CM may be located on the first planarization layer 209a and may be connected to the drain electrode DE of the thin-film transistor TFT through a contact hole defined in the first planarization layer 209a. The connection electrode CM may be connected to the light-emitting diode LED located on the second planarization layer 209b and may function as a link connecting the light-emitting diode LED to the thin-film transistor TFT.

The light-emitting diode LED may be located on the planarization layer 209. The light-emitting diode LED may include an organic light-emitting diode or an inorganic light-emitting diode described with reference to FIGS. 5A to 5C.

A sensing line SEL may be arranged in the pixel area PXA. The sensing line SEL may include a first sensing line SEL1 located on the same layer as the gate electrode GE, a second sensing line SEL2 located on the same layer as the upper electrode CE2 of the storage capacitor Cst, a third sensing line SEL3 located on the same layer as the data line DL, and/or a fourth sensing line SEL4 located on the same layer as the connection electrode CM. The sensing line SEL may be provided as various combinations. For example, the sensing line SEL may include each of the first to fourth sensing lines SEL1 to SEL4 as a single layer or two or more layers. For example, the sensing line SEL may include the third sensing line SEL3 located on the second interlayer insulating layer 207, on which the data line DL may also be located, and the fourth sensing line SEL4 located on the first planarization layer 209a, the third sensing line SEL3 and the fourth sensing line SEL4 being connected to each other through a contact hole. According to some embodiments, the fourth sensing line SEL4 may extend to the non-pixel area NPAX.

The actuator AT for stretching and/or shrinkage and the lines WL configured to supply various signals and/or voltages to the pixel driving circuit portion PC arranged in the pixel area PXA may be arranged in the non-pixel area NPXA of the substrate 100.

When the buffer layer 201, the gate insulating layer 203, the first interlayer insulating layer 205, and the second interlayer insulating layer 207 arranged in the pixel area PXA are referred to as an inorganic material layer IL, the inorganic material layer IL may include an opening OP to correspond to the non-pixel area NPXA. That is, the inorganic material layer IL may be removed from the non-pixel area NPXA. This may be configured to relatively reduce the modulus of the non-pixel area NPXA. Accordingly, the modulus of the non-pixel area NPXA may be less than the modulus of the pixel area PXA.

An organic material layer 202 may be located in the opening OP of the inorganic material layer IL. The organic material layer 202 may include an organic material having less rigidity than an inorganic material, and thus, the non-pixel area NPXA may be easily stretched or shrunk. Also, because the organic material layer 202 may be located below a first line WL1, a height difference between the organic material layer 202 and the first line WL1 may not occur, when the first line WL1 extends to the pixel area PXA.

The organic material layer 202 may include an organic insulating material, such as polyimide, polyamide, acryl resins, BCB, HMDSO, phenol resins, etc. The organic material layer 202 may include a single layer or layers including the organic insulating material as described above.

The actuator AT and the first line WL1 may be located on the organic material layer 202. The actuator AT may include a first actuator AT1 and a second actuator AT2. The first actuator AT1 may be a stretching actuator and the second actuator AT2 may be a shrinkage actuator.

According to some embodiments, the first actuator AT1 and the second actuator AT2 may be DEAs. In this case, the first actuator AT1 and the second actuator AT2 may be mounted in different directions from each other. A wide surface of an electrode layer of the first actuator AT1 may be mounted on an upper surface of the substrate in parallel therewith. A wide surface of an electrode layer of the second actuator AT2 may be mounted to be perpendicular to the upper surface of the substrate. That is, the electrode layer and an elastomer layer of the second actuator AT2 may be arranged in contact with the organic material layer 202.

The first line WL1 may be configured to transmit an electrical signal or a static voltage to the pixel driving circuit portion PC. Alternatively, the first line WL1 may be a sensing line. Alternatively, the first line WL1 may be configured to transmit a signal or a voltage to the actuator AT. The first line WL1 may be electrically connected to the lines arranged in the pixel area PXA. The first line WL1 may include a stretchable material, for example, a highly flexible metal material. According to some embodiments, the first line WL1 may include liquid metal or a mixture of liquid metal and a rubber material. According to some embodiments, the first line WL1 may include nanoparticles, nanoflakes, or nanowires of metal, silver, copper, etc. According to some embodiments, the first line WL1 may include a mixture of a nanostructure including metal, silver, copper, etc. and a rubber material. Alternatively, the first line WL1 may include a carbon nanotube or graphene. The first line WL1 may include a mixture of a carbon-based nanostructure and a rubber material.

The first actuator AT1 and the second actuator AT2 may be covered by the first planarization layer 209a. The first planarization layer 209a may be arranged in both the pixel area PXA and the non-pixel area NPXA. The first planarization layer 209a may be formed on the entire surface of the substrate 100, after the first actuator AT1 and the second actuator AT2 are located on the organic material layer 202.

A first driving signal line AL1, a second driving signal line AL2, and a second line WL2 may be located on the first planarization layer 209a. The first driving signal line AL1 may be connected to an electrode layer of the first actuator AT1 through a contact hole. The second driving signal line AL2 may be connected to an electrode layer of the second actuator AT2 through a contact hole. The second line WL2 may be configured to transmit an electrical signal or a static voltage to the pixel driving circuit portion PC. Alternatively, the second line WL2 may be a sensing line. The second line WL2 may be electrically connected to the lines arranged in the pixel area PXA. The second line WL2 may include a stretchable material, for example, a highly flexible metal material. According to some embodiments, the second line WL2 may include liquid metal or a mixture of liquid metal and a rubber material. According to some embodiments, the second line WL2 may include nanoparticles, nanoflakes, or nanowires of metal, silver, copper, etc. According to some embodiments, the second line WL2 may include a mixture of a nanostructure including metal, silver, copper, etc. and a rubber material. Alternatively, the second line WL2 may include a carbon nanotube or graphene. The second line WL2 may include a mixture of a carbon-based nanostructure and a rubber material.

The second planarization layer 209b may not be located on the first driving signal line AL1, the second driving signal line AL2, and the second line WL2. However, the second planarization layer 209b is not limited thereto. The second planarization layer 209b extending from the pixel area PXA may be located on the first driving signal line AL1, the second driving signal line AL2, and the second line WL2.

FIG. 11A illustrates that the first planarization layer 209a including the materials having the same characteristic throughout the pixel area PXA and the non-pixel area NPXA may cover the first actuator AT1 and the second actuator AT2. However, embodiments according to the present disclosure are not limited thereto.

As illustrated in FIG. 11B, the first planarization layer 209a may include a first-1 planarization layer 209a′ corresponding to the pixel area PXA and a first-2 planarization layer 209a″ corresponding to the non-pixel area NPXA. The first-1 planarization layer 209a′ and the first-2 planarization layer 209a″ may be provided on the same layer as each other while having different moduli from each other. The modulus of the first-1 planarization layer 209a′ may be greater than the modulus of the first-2 planarization layer 209a″. The first-1 planarization layer 209a′ may be formed by spreading a preliminary planarization layer including an organic insulating material throughout the pixel area PXA and the non-pixel area NPXA and then locally applying energy to the pixel area PXA through irradiation of ultraviolet rays, etc. Accordingly, the modulus of the first-1 planarization layer 209a′ may be greater than the modulus of the first-2 planarization layer 209a″.

Alternatively, as illustrated in FIG. 11C, the first planarization layer 209a may be arranged only in the pixel area PXA and may not be arranged on the first actuator AT1 and the second actuator AT2. In this case, the first planarization layer 209a may include a material locally curable.

According to some embodiments, a protective layer 209′ having a less modulus than the first planarization layer 209a may be arranged in the non-pixel area NPXA. According to some embodiments, the protective layer 209′ may not be arranged. Because the first planarization layer 209a may not be arranged in the non-pixel area NPXA, the modulus of the non-pixel area NPAX may be less than the modulus of the pixel area PXA.

The display apparatus according to embodiments may include the actuator AT in the non-pixel area NPXA between the pixel areas PXA, and thus, even when undesired deformation occurs, the display area of the display apparatus may be corrected according to pre-set deformation distribution.

The display apparatus 1 according to the embodiments described above may be used for various electronic devices capable of providing an image. Here, the electronic device may indicate a device using electricity and capable of providing a certain image.

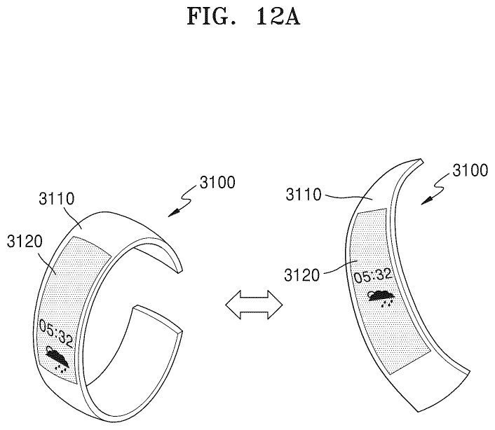

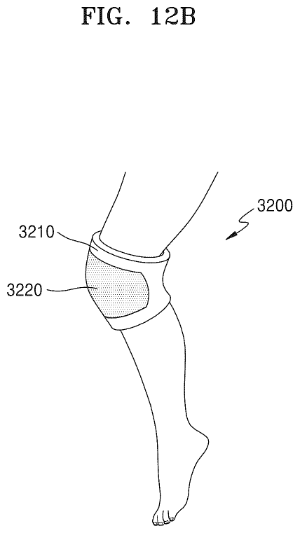

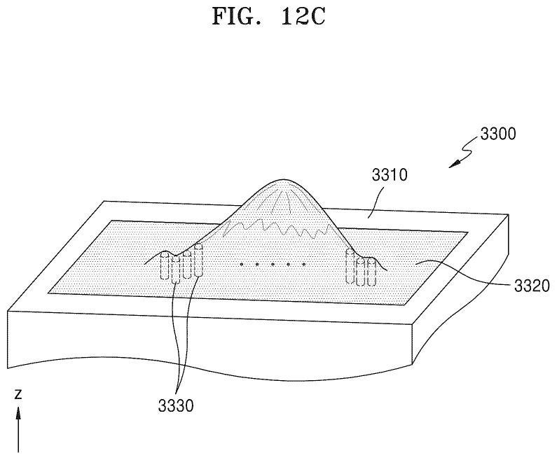

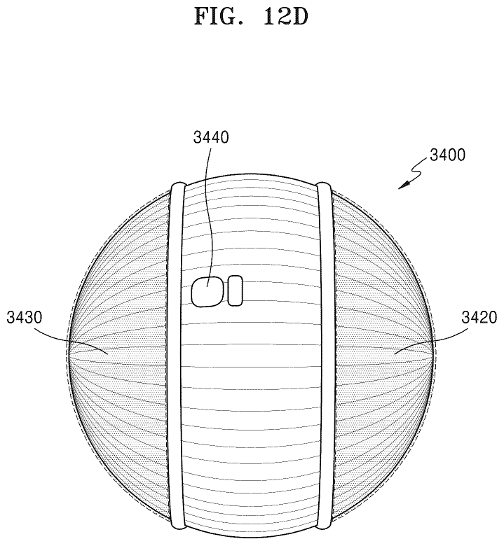

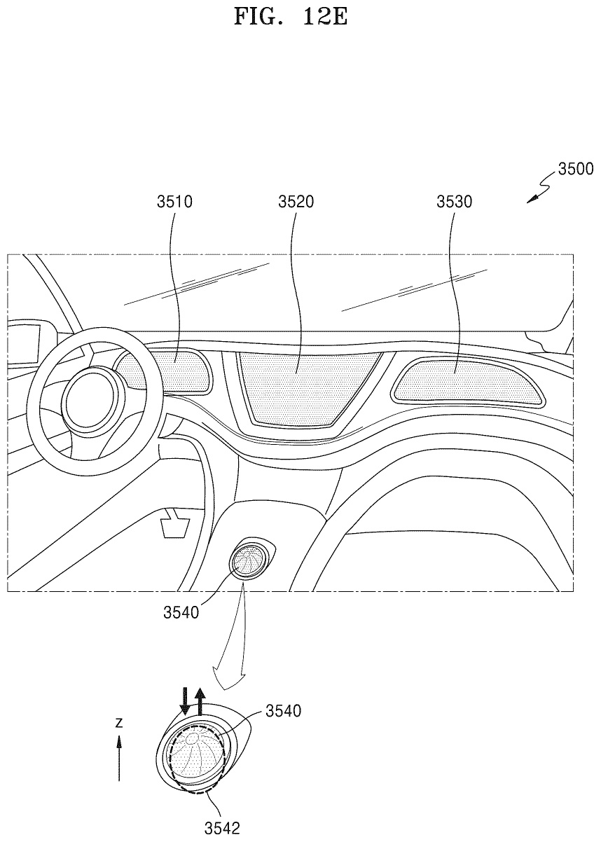

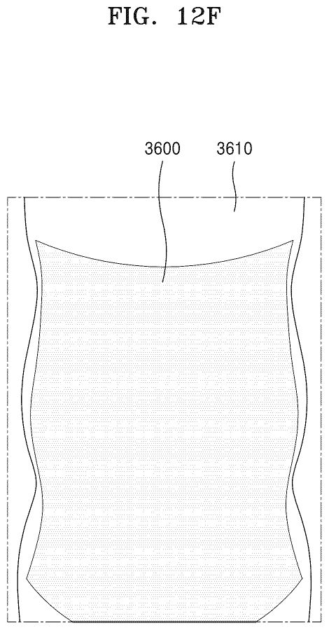

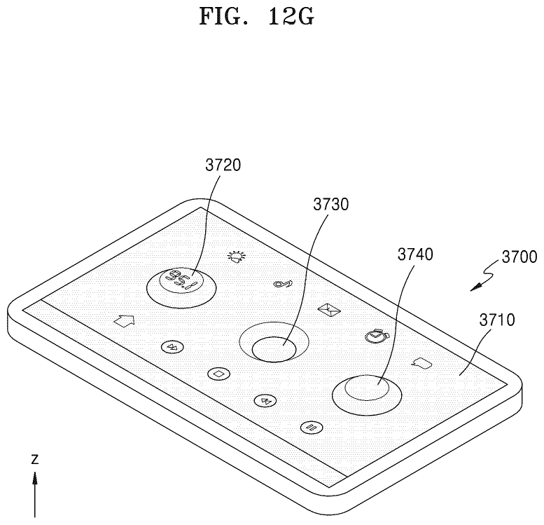

FIGS. 12A to 12G are schematic perspective views of electronic devices including a display apparatus according to some embodiments.

Referring to FIG. 12A, the display apparatus according to some embodiments may be used for a wearable electronic device 3100 which may be worn on a part of a human body of a user. The wearable electronic device 3100 may include a body 3110 and a display 3120 provided in the body 3110. The display apparatus according to embodiments may be used as the display 3120 of the wearable electronic device 3100. The wearable electronic device 3100 may be deformed, as illustrated in FIG. 12A. According to some embodiments, according to selection of a user, the wearable electronic device 3100 may be used as a smart watch or a smartphone.

FIG. 12B illustrates a medical electronic device 3200. According to some embodiments, the medical electronic device 3200 may include a body 3210 and an emission portion 3220. The display apparatus according to embodiments may be used as the emission portion 3220 of the medical electronic device 3200. The emission portion 3220 may emit light of a certain wavelength band (for example, infrared rays, visible rays, etc.) to a human body of a patient. According to some embodiments, the body 3210 may include a flexible fiber material and may have a structure that is wearable on a human body of a user of the emission portion.

FIG. 12C illustrates an educational electronic device 3300. According to some embodiments, the educational electronic device may include a display 3320 provided in a frame 3310. The display 3320 may use the display apparatus according to embodiments. An image such as the sea swelling with waves, mountains covered with snow, volcanoes with flowing flames, or the like may be provided through the display 3320, and in this case, the display 3320 may be stretched in a height direction (for example, a z direction) by reflecting the height of the waves, mountains, or volcanoes. According to some embodiments, a portion of the display 3320 may have a height that is sequentially variable along a direction in which the flames flow, thereby three-dimensionally showing the movement of the flames. The educational electronic device 3300 may include a plurality of pins (or strokes) 3330 arranged at a rear surface of the display 3320 so that the display 3320 may be stretched in a height direction. As the pins 3330 move in a third direction (for example, the z direction or a −z direction), an image represented by the display 3320 may be realized to have a three-dimensional height. FIG. 12C illustrates the educational electronic device 3300. However, the described usage is not limited thereto and may be applied to all devices providing certain image information.

It is described that the electronic devices illustrated in FIGS. 12A to 12C may have variable shapes. However, embodiments according to the present disclosure are not limited thereto. As described according to embodiments below, the display apparatus according to embodiments may be used for an electronic device having a fixed portion (for example, a screen) configured to display an image.

FIG. 12D illustrates a robot 3400 as another electronic device according to some embodiments. The robot 3400 may recognize a movement or an object by using a camera 3440 and may display a certain image for a user through displays 3420 and 3430. According to some embodiments, the display apparatus according to embodiments may be stretched in various directions as described above, and thus, may be assembled into a body frame having a semicircular shape. Thus, the robot 3400 may include the displays 3420 and 3430 having semicircular shapes.

FIG. 12E illustrates a vehicle display device 3500 as an electronic device according to some embodiments. The vehicle display device 3500 may include a cluster 3510, a center information display (CID) 3520, and/or a co-driver display 3530. The display apparatus according to embodiments may be stretched in various directions, and thus, may not be limited by the shape of an internal frame of a vehicle and may be used for the cluster 3510, the CID 3520, and/or the co-driver display 3530.

FIG. 12E illustrates that the cluster 3510, the CID 3520, and/or the co-driver display 3530 are separate devices from each other. However, embodiments according to the present disclosure are not limited thereto. According to some embodiments, two or more selected from among the cluster 3510, the CID 3520, and the co-driver display 3530 may be integrally connected.

According to some embodiments, the vehicle display device 3500 may include a button 3540 configured to display a certain image. With reference to an enlarged view of FIG. 12E, the button 3540 having a semicircular shape may include an object 3542 providing a sense of use of a button by moving in a z direction or a −z direction and a display apparatus located above the object 3542. According some embodiments, when the object 3542 has a three-dimensionally round surface, the display apparatus may also have a three-dimensionally round surface.

FIG. 12F illustrates that the electronic device according to some embodiments may correspond to an electronic device 3600 for advertisement or exhibition. According to some embodiments, the electronic device 3600 for advertisement or exhibition may be mounted on a structure 3610 that is fixed, such as a wall or a pillar. When the structure 3610 includes a concavo-convex surface as illustrated in FIG. 12F, the electronic device 3600 for advertisement or exhibition may also be arranged along the concavo-convex surface of the structure 3610. According to some embodiments, the electronic device 3600 for advertisement or exhibition may be mounted on the structure 3610 by using a thermal contraction film, etc.

FIG. 12G illustrates that the electronic device according to some embodiments corresponds to a controller 3700. The controller 3700 may include an image-type button. For example, the controller 3700 may include first to third button areas 3720, 3730, and 3740 in which portions of a display 3710, protrude in a z direction or protrude in a −z direction (or are recessed from the z direction). According to some embodiments, the first and third button areas 3720 and 3740 may protrude in the z direction, and the second button area 3730 may protrude in the −z direction (or may be recessed from the z direction).

According to some embodiments, a display apparatus which may be stretched in various directions may be provided. The described effect is an example, and the scope of embodiments according to the present disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims, and their equivalents.

What is claimed is:

1. A display apparatus comprising:
a substrate comprising a plurality of emission areas and a non-emission area between the plurality of emission areas;
at least one light-emitting diode in each of the plurality of emission areas;
a sensing line crossing the non-emission area;
one or more actuators in the non-emission area;
a sensing portion configured to sense a deformation rate of the substrate from the sensing line; and
a correction control portion configured to drive the one or more actuators.

2. The display apparatus of claim 1, wherein the deformation rate of the substrate is measured from at least one value from among a resistance change, a capacitance change, and a waveform change according to an electrical signal of the sensing line.

3. The display apparatus of claim 1, wherein the sensing portion comprises:
a memory portion configured to store a reference value of a characteristic of the sensing line; and
a sensing circuit configured to calculate the deformation rate of the substrate by comparing the reference value stored in the memory portion with the characteristic of the sensing line.

4. The display apparatus of claim 1, wherein the correction control portion comprises:
a correction circuit configured to generate a correction value by comparing an average deformation rate of the plurality of emission areas with a deformation rate of each of the plurality of emission areas; and
an actuator circuit configured to generate, based on the correction value, a driving signal for driving the one or more actuators.

5. The display apparatus of claim 1, wherein a modulus of the non-emission area is less than a modulus of the emission areas.

6. The display apparatus of claim 1, wherein the one or more actuators comprise a first actuator and a second actuator, wherein the first actuator is a stretching actuator and the second actuator is a shrinkage actuator.

7. The display apparatus of claim 1, wherein the one or more actuators comprise soft actuators.

8. The display apparatus of claim 1, wherein the one or more actuators comprise dielectric elastomer actuators each including a first electrode layer, an elastomer layer, and a second electrode layer.

9. The display apparatus of claim 1, further comprising a scan line crossing the plurality of emission areas and extending in a first direction,
wherein the sensing line extends in a second direction crossing the first direction.

10. The display apparatus of claim 1, wherein the at least one light-emitting diode comprises an organic light-emitting diode or an inorganic light-emitting diode.

11. A display apparatus comprising:
a substrate comprising a plurality of emission areas and a non-emission area between the plurality of emission areas;
at least one light-emitting diode in each of the plurality of emission areas;
a scan line crossing the plurality of emission areas and extending in a first direction;
a sensing line crossing the non-emission area and extending in a second direction crossing the first direction; and
a first actuator and a second actuator in the non-emission area,
wherein the first actuator includes a stretching actuator and the second actuator includes a shrinkage actuator.

12. The display apparatus of claim 11, wherein a modulus of the non-emission area is less than a modulus of the emission areas.

13. The display apparatus of claim 11, further comprising an inorganic insulating layer between the substrate and the at least one light-emitting diode,
wherein the inorganic insulating layer has an opening corresponding to the non-emission area.

14. The display apparatus of claim 13, wherein an organic material layer is in the opening of the inorganic insulating layer.

15. The display apparatus of claim 11, wherein the first actuator and the second actuator are between adjacent emission areas in the first direction.

16. The display apparatus of claim 11, wherein each of the first actuator and the second actuator comprises a dielectric elastomer actuator including a first electrode layer, an elastomer layer, and a second electrode layer.

17. The display apparatus of claim 11, further comprising:
a sensing portion configured to sense a deformation rate of the substrate from the sensing line; and
a correction control potion configured to drive the first actuator and the second actuator.

18. The display apparatus of claim 17, wherein the deformation rate of the substrate is measured from at least one value from among a resistance change, a capacitance change, and a waveform change according to an electrical signal of the sensing line.

19. The display apparatus of claim 17, wherein the sensing portion comprises:
a memory portion configured to store a reference value of a characteristic of the sensing line; and
a sensing circuit configured to calculate the deformation rate by comparing the reference value stored in the memory portion with the characteristic of the sensing line.

20. The display apparatus of claim 17, wherein the correction control portion comprises:
a correction circuit configured to generate a correction value by comparing an average deformation rate of the plurality of emission areas with a deformation rate of each of the plurality of emission areas; and
an actuator circuit configured to generate, based on the correction value, a driving signal for driving the first and second actuators.
